(19) United States
(12) Patent Application Publication
(10) Pub. No.: US 2022/0170164 A1
(43) Pub. Date: Jun. 2, 2022

(54) METHOD FOR PRODUCING A STEEL STRIP WITH IMPROVED BONDING OF METALLIC HOT-DIP COATINGS

(71) Applicant: Salzgitter Flachstahl GmbH, Salzgitter (DE)

(72) Inventors: Kai Köhler, Nordstemmen (DE); Nils Köpper, Harsum (DE); Friedrich Luther, Gehrden (DE); Marc Debeaux, Hildesheim (DE)

(21) Appl. No.: 17/599,961

(22) PCT Filed: Mar. 27, 2020
(86) PCT No.: PCT/EP2020/058809

§ 371 Date: Sep. 29, 2021

(30) Foreign Application Priority Data
Apr. 1, 2019 (DE) 10 2019 108 459.8

(51) Int. Cl. C23C 28/02; B32B 15/01; C22C 38/38; C22C 38/32; C22C 38/28; C22C 38/26; C22C 38/24; C22C 38/22; C22C 38/06; C22C 38/02; C22C 38/00; C21D 9/52; C21D 6/00; C23C 2/02; C23C 2/06; C23C 2/12; C23C 2/28; C23C 2/40; C23C 14/16; C23C 16/06; C25D 3/20; C25D 11/34; C25D 5/10; C25D 5/36; C25D 5/50; C25D 7/06; C25D 17/00

(52) U.S. Cl. CPC C23C 28/021; C25D 17/00; B32B 15/013; C22C 38/38; C22C 38/32; C22C 38/28; C22C 38/26; C22C 38/24; C22C 38/22; C22C 38/06; C22C 38/02; C22C 38/002; C21D 9/52; C21D 6/008; C21D 6/005; C21D 6/002; C23C 2/02; C23C 2/06; C23C 2/12; C23C 2/28; C23C 2/40; C23C 14/16; C23C 16/06; C25D 3/20; C25D 11/34; C25D 5/10; C25D 5/36; C25D 5/50; C25D 7/0614; B32B 15/012

(57) ABSTRACT

A cold- or hot-rolled steel strip with a metallic coating, the steel strip having iron as the main constituent and, in addition to carbon, an Mn content of 8.1 to 25.0 wt. % and optionally one or more of the alloying elements Al, Si, Cr, B, Ti, V, Nb and/or Mo. The uncoated steel strip is first cleaned, a layer of pure iron is applied to the cleaned surface, an oxygen-containing, iron-based layer containing more than five mass percent of oxygen is applied to the layer of pure iron. The steel strip is then annealed and is reduction-treated in a reducing furnace atmosphere during the annealing treatment to obtain a surface consisting mainly of metallic iron. The steel strip is then hot-dip coated with the metallic coating. This creates uniform and reproducible bonding conditions for the coating on the steel strip surface.

### CROSS REFERENCE TO RELATED APPLICATION

The present application claims the priority benefits of International Patent Application No. PCT/EP2020/058809, filed Mar. 27, 2020, and claims benefit of German patent application DE 10 2019 108 459.8, filed Apr. 1, 2019.

### BACKGROUND AND FIELD OF THE INVENTION

The invention relates to a method for producing a cold-rolled or hot-rolled steel strip having a metallic coat, the steel strip comprises iron as a main constituent and, in addition to carbon, an Mn content of 8.1 to 25.0 wt. % and optionally one or more of the alloy elements Al, Si, Cr, B, Ti, V, Nb and/or Mo. Furthermore, the invention relates to a steel strip with a metallic coat applied by means of hot-dipping, and to the use of such a steel strip.

The following are known inter alia for the coatings or alloy coatings applied by hot-dipping: aluminium-silicon (AS/AlSi), zinc (Z), zinc-aluminium (ZA), zinc-iron (ZF/galvannealed), zinc-magnesium-aluminium (ZM/ZAM) and aluminium-zinc (AZ). These corrosion protection coatings are typically applied to the steel strip (hot strip or cold strip) in continuous feed-through processes in a melting bath.

Laid-open document WO 2013/007578 A2 discloses that high strength steels having higher contents of elements in wt. % of up to 35.0% Mn, up to 10.0% Al, up to 10.0% Si, up to 5.0% Cr form, during the course of the annealing of the steel strip upstream of the hot-dip coating procedure, selectively passive, non-wettable oxides on the steel surface, whereby the bonding of the coat on the steel strip surface is impaired and this can result at the same time in the formation of non-galvanised locations. These oxides are formed by reason of the prevailing annealing atmosphere which inevitably always contains small traces of H₂O or O₂ and has an oxidising effect on said elements.

The document discloses inter alia a method in which, during the course of annealing under oxidising conditions in a first step pre-oxidation of the steel strip takes place, by means of which an FeO layer providing targeted covering is produced which prevents selective external oxidation of the alloy elements. In a second step, this layer is then reduced to form metallic iron.

Patent document DE 10 2013 105 378 B3 discloses a method for producing a flat steel product which contains, in addition to iron and unavoidable impurities, the following in wt. %: up to 35 Mn, up to 10 Al, up to 10 Si and up to 5 Cr. After heating in a pre-heating furnace, in which the flat steel product is subjected to an oxidising atmosphere and recrystallisation annealing in the annealing furnace, in which an annealing atmosphere acting in a reducing manner with respect to FeO prevails, the flat steel product is coated in the hot-dip bath.

Laid-open document DE 10 2010 037 254 A1 discloses a method for hot-dip coating of a flat steel product, wherein the flat steel product is produced from a rust-proof steel which contains, in addition to iron and unavoidable impurities, the following in wt. %: 5 to 30 Cr, <6 Mn, <2 Si and <0.2 Al. The flat steel product is first heated in an oxidising pre-oxidation atmosphere, then held under a reducing holding atmosphere and then passed through a melting bath.

From patent document DE 693 12 003 T2 a method is also known for the production of a coated steel sheet with reduced surface flaws, wherein a coating of zinc or a zinc alloy is applied to at least one surface of a steel strip. In addition, immediately below the zinc or zinc alloy coating, a layer of Fe is provided and, immediately below the layer of Fe, a layer in which oxygen-affine elements of the steel are concentrated is provided. The low-carbon or very low-carbon steel strip to which the Fe-plating is applied contains at least one component selected from the group: Si, Mn, P, Ti, Nb, Al, Ni, Cu, Mo, V, Cr and B in a quantity of at least 0.1 wt. % for Si, Ti, Ni, Cu, Mo, Cr and V and at least 0.5 wt. % for Mn, at least 0.05 wt. % for P, Al and Nb and at least 0.001 wt. % for B. The Fe layer comprises an application weight of 0.1 to 10 g/m², an oxygen content of 0.1 to 10 wt. % and a carbon content of 0.01 wt. % to less than 10 wt. %. In this case, the target should be that, at the boundary surface between the oxygen-containing Fe layer and the steel strip, a layer is produced during the annealing prior to the hot-dip coating in which oxygen-affine elements contained in the steel are concentrated. In this way, the further diffusion of the oxygen-affine elements contained in the steel in the direction of the Fe plate surface should be prevented and good galvanising capability achieved.

Furthermore, from laid-open document US 2018/0 119 263 Al a method is known for producing a cold-rolled steel strip with an Mn content between 1 and 6 wt. % and a C content less than 0.3 wt. % and with a metallic coat. In this case, the steel strip is electroplated with a layer of pure iron, the iron layer is then oxidised to form an iron oxide layer and then reduced at a temperature between 750° C. and 900° C. in an atmosphere with 1 to 20 vol. % hydrogen. A zinc coat is then applied by hot-dip coating.

In laid-open document US 2004/0 121 162 Al a cold-rolled or hot-rolled steel strip with up to 0.5 wt. % C and with up to 15 wt. % Mn and with a coating is also already described. The coating comprises, starting from the steel strip, iron plating and a metallic zinc coat.

Furthermore, laid-open document CN 109 477 191 A discloses a further cold-rolled or hot-rolled coated steel strip with a coating. The steel strip comprises 0.08 to 0.3 wt. % C, 3.1 to 8.0 wt. % Mn, 0.01 to 2.0 wt. % Si, 0.001 to 0.5 wt. % Al. The coating consists of a layer based on elemental iron and a metallic coat applied thereto by means of hot-dip coating. The metallic coat is made from zinc, zinc-iron, zinc-aluminium or zinc-aluminium-magnesium.

In laid-open document EP 2 918 696 A1 a further steel strip of 0.05 to 0.50 wt. % C, 0.5 to 5.0 wt. % Mn, 0.2 to 3.0 wt. % Si and 0.001 to 1.0 wt. % Al is described, which is hot-dip coated with a Zn—Fe alloy. The steel strip has at its boundary surface with respect to the Zn—Fe coating a layer with at least 50 vol. % ferrite and at least 90% non-oxidised iron.

Furthermore, laid-open document WO 2015/001 367 Al discloses a steel strip with an Mn content between 3.5 and 10.0 wt. % and a C content between 0.1 and 0.5 wt. %, on which a lower layer of pure ferrite with a layer thickness between 10 and 50 μm, a further lower layer of iron and oxides with a layer thickness between 1 and 8 μm and a cover layer of pure iron with a layer thickness of 50 to 300 nm is disposed. A hot-dip coating with Al, Zn or alloys thereof is carried out on the cover layer.

However, it has proved to be the case that in the case of Mn contents of over 8.1 to 25.0 wt. % in the steel in all previously known solutions for the improvement of the wettability of the steel surface, no satisfactory reproducible adhesion of the coat can be achieved.

The reason for this is the formation of a solid margin of oxides of the alloy elements on the underside of the iron oxide layer (which has then been reduced after a reducing annealing process) or oxygen-containing iron layer. This oxide margin consisting of oxides of the alloy elements is a weak point in the system when it comes to adhesion. This means that at the boundary surface of the reduced iron oxide layer or oxygen-containing iron layer with respect to the steel substrate, an adhesion failure can often be observed at this point e.g. during a deformation process.

### SUMMARY OF THE INVENTION

The present invention provides a method for producing a cold-rolled or hot-rolled steel strip with a metallic coat, which, in addition to carbon, contains iron as a main constituent, an Mn content of 8.1 to 25.0 wt. % and optionally further oxygen-affine elements such as e.g. Al, Si, Cr, B, which provides uniform and reproducible adhesion conditions for the coat on the steel strip surface irrespective of the actual alloy composition of the steel strip.

The embodiments of the invention include a method for producing a cold-rolled or hot-rolled steel strip having a metallic coat with improved adhesion, the steel strip comprises iron as a main constituent and, in addition to carbon, an Mn content of 8.1 to 25.0 wt. % and optionally one or more of the alloy elements Al, Si, Cr, B, Ti, V, Nb and/or Mo, wherein the surface of the uncoated steel strip is first cleaned and then a layer of pure iron is applied onto the cleaned surface, onto the layer of pure iron an oxygen-containing, iron-based layer is applied, which layer contains more than 5 mass percent of oxygen, then the steel strip together with the oxygen-containing, iron-based layer is subjected to annealing treatment and, in order to achieve a surface consisting substantially of metallic iron, is reduction-treated during the course of the annealing treatment in a reducing furnace atmosphere and the steel strip thus treated and subjected to annealing treatment is then hot-dip coated with the metallic coat.

Furthermore, an aspect of the invention also comprises a steel strip comprising, in addition to carbon, iron as a main constituent, an Mn content of 8.1 to 25.0 wt. % and optionally one or more of the alloy elements Al, Si, Cr, B, Ti, V, Nb and/or Mo with a metallic coat applied by means of hot-dipping to the steel strip surface, which is characterised in that, in the transition region between the metallic coat and the steel strip surface, a predominantly ferritic edge zone with more than 51 vol. % ferrite is formed which has a thickness of 0.25 to 1.3 μm.

The invention further comprises the use of a steel strip in accordance with the invention for the production of parts of motor vehicles.

### DESCRIPTION OF THE PREFERRED EMBODIMENTS

The invention is embodied as a combination of a pure iron coating applied to the steel strip surface with an oxygen-containing iron coating deposited thereover with subsequent annealing and hot-dip finishing.

In terms of the present invention, a pure iron layer is understood to be a layer with an average iron content of more than 96 wt. %. The oxygen-containing, iron-based layer is understood to be a layer with an iron content in wt. % of at least 50%, which contains oxygen of more than 5 wt. % in the form of oxides and/or hydroxides.

The oxides and/or hydroxides can be present in the oxygen-containing, iron-based layer both in the form of crystalline, amorphous compounds and/or as mixtures of crystalline, e.g. magnetite (Fe₃O₄), and amorphous compounds. In addition, the oxygen-containing, iron-based layer is understood to be both a homogeneous stoichiometric iron-oxide layer e.g. a magnetite layer (Fe₃O₄), and also a metallic iron layer which contains oxidic and/or hydroxidic inclusions (dispersion layer). Therefore, the distribution of the amorphous and/or crystalline compounds is also not limited. Therefore the layer is characterised in that it contains oxygen-containing, reducible iron species.

In trials it has proved to be the case that without a pre-coating of pure iron, during the annealing treatment prior to the hot-dip coating, a solid deposition of oxides of the alloy elements takes place at the transition from the steel substrate to the oxygen-containing, iron-based layer, which weakens the whole system and can lead to adhesion failure. With the pre-coating of pure iron, the oxides of the alloy elements are deposited in a less locally concentrated manner and adhesion failure no longer occurs. The deposition of the pure iron layer can preferably take place electrolytically or by deposition from the vapour phase (e.g. by means of PVD or CVD).

In the case of the preferred electrolytic deposition of the pure iron layer, typically sulphatic or chloridic electrolytes and combinations thereof are used, the pH value of which is less than or equal to 5.5. In the case of higher pH values, iron(II) species precipitate as hydroxides. Iron with a purity in wt. % of greater than 99.5 is preferably used as the anode material. Electrolyte cells with separated anode and cathode chambers can also be used, whereby the use of oxygen-generating or insoluble anodes is rendered possible. In order to reduce the cell resistance a conductive salt can optionally be added to the electrolyte. The use of further additives, such as e.g. surfactants to improve wetting and/or defoaming is also possible.

The electrolytic deposition takes place at current densities which produce a deposition thickness which is homogeneous over the strip length irrespective of the respective strip speed. Furthermore, the current density is dependent upon the anode construction length in the running direction of the strip. Typically values are between 1 and 150 A/dm² per strip side. Below 1 A/dm² excessively long processing lengths are required and consequently the process cannot be operated economically. In the case of current densities above 150 A/dm² a homogeneous deposition is rendered significantly more difficult owing to burning-on or dendrite formation. The duration of the electrolytic deposition is dependent on the processing length, the current density, the current yield and the desired layer contact and is typically between 1 s and 30 s per side. Exemplified compositions of aqueous electrolytes and deposition conditions are shown in Table 1.

TABLE 1

| Electrolyte system | Composition | Conditions |
|---|---|---|
| Sulphate | FeSO₄•7H₂O: 220 g/l | pH 2.2; 35° C. |
| | NaSO₄: 90 g/l | |
| Chloride | FeCl₂•4H₂O: 280 g/l | pH 1.4; 48° C. |
| | KCI: 210 g/l | |
| Sulphate chloride | FeSO₄•7H₂O: 400 g/l | pH 1.6; 85° C. |
| | FeCl₂•4H₂O: 400 g/l | |
| | CaCl₂: 180 g/l | |
| Sulphamate | Fe(SO₃NH₂)₂: 220 g/l | pH 3.2; 60° C. |
| | NH₄(SO₃NH₂): 30 g/l | |
| Fluoroborate | Fe(BF₄)₂: 240 g/l | pH 2.1; 58° C. |
| | NaCl: 8 g/l | |

In one exemplified embodiment, the deposition of the pure iron layer takes place with an electrolyte temperature of 60° C. with a current density of 30 A/dm² using an iron anode with a purity in wt. % of greater than 99.5 in an aqueous sulphuric acid electrolyte of the following composition: 60 g/I iron(II), 20 g/I sodium, pH 1.8.

The preferred deposition of the oxygen-containing, iron-based layer takes place electrolytically from an Fe(II)-containing and/or Fe(III)-containing electrolyte. For this purpose, sulphatic or chloridic electrolytes and combinations thereof are typically used, the pH value of which is generally less than or equal to 5.5.

However, the use of a basic electrolyte with a pH value>10 is possible when using a suitable complexing agent such as e.g. triethanolamine (TEA). The electrolytic deposition takes place at current densities which produce a homogeneous deposition thickness over the strip length irrespective of the respective strip speed. Furthermore, the current density is dependent upon the anode construction length in the running direction of the strip. Typical values are between 1 and 150 A/dm² per strip side. Below 1 A/dm² excessively long processing lengths are required and consequently the process cannot be operated economically. In the case of current densities above 150 A/dm² a homogeneous deposition is rendered significantly more difficult owing to burning-on or dendrite formation. The deposition time is dependent on the processing length, the current density, the current yield and the desired layer contact and is typically between 1 and 30 s per side. Exemplified compositions of aqueous electrolytes and deposition conditions are shown in Table 2.

TABLE 2

| Complexing agent | Composition | Conditions |
|---|---|---|
| Citrate | FeSO₄•7H₂O: 350 g/l | pH 2,3; 45° C. |
| | Fe₂(SO₄)₃: 10 g/l | |
| | Na₂SO₄: 110 g/l | |
| | Sodium citrate 20 g/l | |
| Triethanolamine | Fe₂(SO₄)₃: 170 g/l | pH 13; 80° C. |
| | NaOH: 12 g/l | |
| | C₆H₁₅NO₃: 15 g/l | |

In order to generate oxygen-containing, iron-based layers, a complexing agent for the iron ions is also required in addition to said Fe(II) and Fe(III) ions in the acid electrolyte. This is typically a compound with one or more carbonyl functionalities such as citric acid, acetic acid or even nitriloacetic acid (NTA) or ethanolamine.

Iron with a purity in wt. % of greater than 99.5 is preferably used as the anode material. Electrolyte cells with separated anode and cathode chambers can also be used, whereby the use of oxygen-generating or insoluble anodes is rendered possible. In order to reduce the cell resistance a conductive salt can optionally be added to the electrolyte. The use of further additives, such as e.g. surfactants to improve wetting or defoaming is also possible.

In one exemplified embodiment, the deposition of the oxygen-containing iron layer takes place at 60° C. with a current density of 30 A/dm² using an iron anode with a purity in wt. % of greater than 99.5 in an aqueous sulphuric acid electrolyte with the following composition: 60 g/I iron(II), 3 g/I iron(III), 25 g/I sodium, 11 g/I citrate, pH 1.8.

In a preferred large-scale implementation, the surface of the steel strip is activated prior to the deposition with the pure iron layer preferably by cleaning in a usually alkaline aqueous medium and a subsequent optional deoxidation in an acid aqueous medium. A sulphuric acid bath with an acid content of 20 to 70 g/I at temperatures of 30 to 70° C. is preferably used for the deoxidation. The subsequent coating with the oxygen-containing, iron-based layer onto the previously deposited pure iron layer is preferably effected wet-in-wet or after drying of the steel strip surface. After the deposition of the oxygen-containing, iron-based layer the steel strip surface is preferably dried in order to prevent undefined ingress of water into the annealing furnace atmosphere. In order to prevent impurities on the steel strip surface and/or carry-over between the different process media, a rinse can optionally be used after each process step. The deposition of the layers can thus take place within one or a plurality of electrolyte cells disposed one after another, the construction of which is preferably horizontal or vertical.

Trials have shown that as a result of the pre-coating with pure iron, the oxygen-containing, iron-based layer is deposited in a particularly finely crystalline form and leads to better adhesion of the hot-dip coat than when the oxygen-containing, iron-based layer is applied directly to the steel surface. Of course, the pre-coating with pure iron clearly significantly improves the nucleation conditions for the subsequent oxygen-containing, iron-based layer, whereby the nucleation rate is increased and the crystallite size therefore decreases compared to a single layer system.

In advantageous developments of the invention, provision is made for the pure iron layer to be formed with an average thickness of 0.05 to 0.6 μm and the oxygen-containing, iron-based layer with an average thickness of 0.2 to 0.7 μm. It has proved to be advantageous for improved adhesion conditions of the hot-dip coat if the pure iron layer has an average thickness of 0.1 to 0.4 μm and the oxygen-containing, iron-based layer an average thickness of 0.3 to 0.6 μm. In addition it is advantageous for the adhesion of the hot-dip coat if the average thickness of the oxygen-containing, iron-based layer is greater than the average thickness of the pure iron layer.

In a further embodiment of the invention, the oxygen-containing, iron-based layer has an oxygen proportion of more than 5 to 40 wt. %, advantageously more than 10 to 30 wt. %. In a particularly advantageous embodiment of the invention, this layer has an oxygen content of more than 12 to 25 wt. %.

In trials it has proved to be the case that the more oxygen is incorporated into the iron layer the more strongly the disadvantageous external oxidation of alloy elements on the surface can be suppressed since this oxygen is used by the alloy elements for internal oxidation during the annealing prior to the hot-dip coating. However, the quantity of the oxygen incorporated into the oxygen-containing, iron-based layer is dependent to a considerable degree on the deposition conditions. Owing to technical and economic boundary conditions, the expedient maximum value for the oxygen content is 40 wt. %.

The pure iron layer itself can be applied in accordance with the invention either electrolytically or by deposition from the vapour phase, while the oxygen-containing, iron-based layer is advantageously deposited electrolytically. A layer with an average iron content of more than 96 wt. % is understood as a pure iron layer.

The steel substrate for a steel strip produced in accordance with the invention with a metallic hot-dip coat can have the following composition in wt. %:

C: 0.1% to 1.0%,

Mn: 8.1% to 25.0%,

Si: 0.01% to 3.0%,

Al: 1.0% to 8.0%,

optionally

Cr: 0.01% to 0.7%,

B: 0.001% to 0.08%,

Ti: 0.005% to 0.3%,

V: 0.005% to 0.3%,

Nb: 0.005% to 0.2%,

Mo: 0.005% to 0.7%,

P: ≤0.10%,

S: ≤0.010%,

with the remainder being iron and unavoidable impurities.

The method in accordance with the invention also comprises an annealing treatment of the steel strip, provided with a pure iron layer and an oxygen-containing, iron-based layer applied thereto, in a continuous annealing furnace. This furnace can be a combination of a furnace part with open combustion (DFF, direct fired furnace/NOF, non-oxidising furnace) and a radiant tube furnace (RTF) disposed downstream thereof or can even take place in an all radiant tube furnace. The steel strip is annealed at an annealing temperature of 550° C. to 880° C. and an average heating rate of 1 K/s to 100 K/s, and a holding time of the steel strip at the annealing temperature between 30 s and 650 s. In the radiant tube furnace a reducing annealing atmosphere consisting of 2% to 40% H₂ and 98 to 60% N₂ and a dew point between +15° C. and −70° C. is used. Then the strip is cooled to a temperature above the melting bath temperature of the coat and subsequently coated with the metallic coat. Optionally, after the annealing treatment and before the coating with the metallic coat, the strip can be cooled to a so-called overaging temperature between 200° C. and 600° C. and held at this temperature for up to 500 s. If an overaging temperature below the melting bath temperature of the coat is selected in order e.g. to influence the microstructure and the resulting technological characteristic values of the steel, the strip can be reheated, e.g. by inductive heating, prior to entry into the melting bath, to a temperature above the melting bath temperature between 400° C. and 750° C. in order not to extract heat from the melting bath by reason of the cold steel strip.

The use of the pre-coatings in accordance with the invention renders an additional introduction of steam in order to increase the dew point, as in the previously known methods, unnecessary. For the annealing atmosphere in the furnace it has therefore proved sufficient for the ratio of the partial pressures of the steam and hydrogen during the annealing in the radiant tube furnace to be in the range of 0.00077>pH₂O/pH_{2>0.00021}, advantageously between 0.00254>pH₂O/pH₂>0.00021.

An exemplified advantageous implementation of the method for the production of a steel strip in accordance with the invention with improved adhesion of a hot-dip galvanisation makes provision that a hot-rolled steel strip (hot strip) is first acid-cleaned then cold-rolled and then galvanised in a hot-dip galvanising line. Within the hot-dip galvanising line the strip passes through a pre-cleaning section, after the pre-cleaning the strip passes further through a strip activation (acid-cleaning/deoxidation) and subsequently 6 electrolyte cells. In the first 3 cells, an iron layer is deposited, in the following 3 cells an oxygen-containing, iron-based layer. The coated strip then passes through a rinse and drying. The strip then passes into the furnace section of the galvanising line, is annealed and galvanised.

Metallic coats for the steel strip annealed in this manner can be e.g. aluminium-silicon (AS, AlSi), zinc (Z), zinc-aluminium (ZA, galfan), zinc-aluminium-iron (ZF, galvannealed), zinc-magnesium-aluminium (ZM, ZAM) or aluminium-zinc (AZ, galvalume). In one embodiment the metallic coat is based on zinc and the zinc coat contains 0.1 to 1 wt. % Al or 0.1 to 6 wt. % Al and 0.1 to 6 wt. % Mg or 5 to 15 wt. % Fe.

A steel strip in accordance with the invention is further characterised in that in the transition region between the metallic coat and the steel strip surface a predominantly ferritic edge zone with more than 60 vol. % ferrite is formed which advantageously has a thickness of 0.25 to 1.3 μm and particularly advantageously a thickness between 0.3 and 1.0 μm. The thickness of this edge zone results directly from the deposited pre-coatings, which, even after annealing and hot-dip coating, has microstructure characteristics deviating from the steel substrate and therefore the desired positive effects.

Table 3 shows the results of aluminization trials which were carried out on a hot-dip simulator with sample sheets of high-manganese steel (15 mass percent Mn and 5 mass percent Si+Al). The deposition of the pre-coatings was carried out electrolytically with a current density of 75 A/dm² per side. The trials were carried out with a heat treatment at 850° C. for 270 seconds. Samples with complete coat wetting and good coat adhesion could be achieved only by means of a pre-coating of pure iron and pre-coating of an oxygen-containing, iron-based layer disposed thereover.

The coat adhesion was tested by means of a ball impact test according to SEP1931. In this test, a semi-spherical stamp is struck with high impact energy against a sample sheet. A cup-shaped impression is made in the sample sheet by the impact force. This process is carried out—possibly a number of times—until an incipient crack is produced in the sample sheet. The surface is then checked visually for detachment and scaling of the coat in the region of the cup. The result is evaluated with scores from 1-4 (scores 1+2 pass, scores 3+4 fail).

TABLE 3

| | | | Oxygen- | | | | | Aluminisation | | |
|---|---|---|---|---|---|---|---|---|---|---|
| | | | containing, iron- | | Annealing (5% | | | (Al + 12% Si) | | |
| | Pure iron layer | | based layer | | H_{₂}—N_{₂}) | | | | Adhesion check | In accordance |
| | Deposition | Thickness/ | Deposition | Thickness/ | Temp./ | Time/ | DP/ | Wet | (Ball impact test | with the |
| No. | time/s | μm | time/s | μm | ° C. | s | ° C. | surface/% | according to SEP1931) | invention |
| 1 | — | — | — | — | 850 | 270 | −50 | <5 | — | NO |
| 2 | 1.5 | 0.23 | 3 | 0.45 | 850 | 270 | −50 | >90 | Score 1 | YES |
| 3 | 3 | 0.45 | 3 | 0.45 | 850 | 270 | −50 | >90 | Score 2 | YES |

Advantages of the invention include the following: (i) reproducible good adhesion of the metallic coat to the steel substrate; (ii) improvement of the galvanising capability of steels with high manganese contents between 8.1 and 25 mass percent; and (iii) improvement in the visual surface quality of the hot-dip coat. Moreover, to date it has often only been possible to galvanise steels with very high alloy element contents on a large scale by means of electrolytic galvanisation and they have tended to suffer from hydrogen embrittlement owing to the hydrogen introduced during this process; this risk does not arise with the hot-dip coating in accordance with the invention. It is the case that in the electrolytic deposition in accordance with the invention, hydrogen can also be formed as a by-product on the cathode and is initially present in atomically adsorbed form on the surface and can be absorbed by the steel substrate later in the process. However, during the subsequent annealing process, the conditions for the effusion of the incorporated hydrogen are present.

1.-20. (canceled)

21. A method for producing a cold-rolled or hot-rolled steel strip having a metallic coat, where the steel strip comprises iron as a main constituent and, in addition to carbon, an Mn content of 8.1 to 25.0 wt. % and optionally one or more of the alloy elements Al, Si, Cr, B, Ti, V, Nb and/or Mo, said method comprising:
cleaning the surface of the uncoated steel strip;
applying a layer of pure iron with an average iron content of more than 96 wt. % onto the cleaned surface;
applying onto the layer of pure iron an oxygen-containing, iron-based layer, which layer contains more than 5 mass percent of oxygen;
subjecting the steel strip together with the oxygen-containing, iron-based layer to annealing treatment, wherein during the course of the annealing treatment the steel strip is reduction-treated in a reducing furnace atmosphere; and
hot-dip coating the steel strip with a metallic coat after the steel strip has been subjected to the annealing treatment and reduction-treated.

22. The method as claimed in claim 21, wherein an average thickness of the pure iron layer is formed to be 0.05 to 0.6 μm and an average thickness of the oxygen-containing, iron-based layer is formed to be 0.2 to 0.7 μm.

23. The method as claimed in claim 21, wherein the average thickness of the pure iron layer is formed to be 0.1 to 0.4 μm and an average thickness of the oxygen-containing, iron-based layer is formed to be from 0.3 to 0.6 μm.

24. The method as claimed in claim 21, wherein the average thickness of the oxygen-containing, iron-based layer is greater than the average thickness of the pure iron layer.

25. The method as claimed in claim 21, wherein the oxygen-containing, iron-based layer has a proportion of oxygen of more than 5 to 40 wt. % and is applied to the pure iron layer.

26. The method as claimed in claim 25, wherein the oxygen-containing, iron-based layer has a proportion of oxygen of more than 10 to 30 wt. % and is applied to the pure iron layer.

27. The method as claimed in claim 25, wherein the oxygen-containing, iron-based layer has a proportion of oxygen of more than 12 to 25 wt. %.

28. The method as claimed in claim 21, wherein the pure iron layer is deposited electrolytically or by deposition from the vapor phase and the oxygen-containing, iron-based layer is deposited electrolytically.

29. The method as claimed in claim 21, wherein the steel strip comprises the following composition in wt. %:
C: 0.1% to 1.0%,
Mn: 8.1% to 25.0%,
Si: 0.01% to 3.0%,
Al: 1.0% to 8.0%,
optionally
Cr: 0.01% to 0.7%,
B: 0.001% to 0.08%,
Ti: 0.005% to 0.3%,
V: 0.005% to 0.3%,
Nb: 0.005% to 0.2%,
Mo: 0.005% to 0.7%,
P: ≤0.10%,
S: ≤0.010%,
with the remainder being iron and unavoidable impurities.

30. The method as claimed in claim 21, wherein the annealing treatment is carried out in a radiant tube furnace as a continuous annealing furnace, at an annealing temperature of 550° C. to 880° C. and an average heating rate of 1 K/s to 100 K/s, with a reducing annealing atmosphere, consisting of 2 to 40% H₂ and 98 to 60% N₂ and a dew point in the annealing furnace between +15 and −70° C. and a holding time of the steel strip at annealing temperature between 30 s and 650 s with optional subsequent cooling to a holding temperature between 200° C. and 600° C. for up to 500 s with subsequent optional inductive heating to a temperature above the melting bath temperature of the metallic coat at 400° C. to 750° C. and subsequently hot-dip coating of the steel strip with the metallic coat is carried out.

31. The method as claimed in claim 30, wherein a ratio of the partial pressures of steam and hydrogen during the annealing in the radiant tube furnace is in the range of 0.00077>pH₂O/pH₂>0.00021.

32. The method as claimed in claim 21, wherein the following are used as metallic coats: aluminium-silicon (AS, AlSi), zinc (Z), zinc-aluminium (ZA, galfan), zinc-iron (ZF, galvannealed), zinc-aluminium-magnesium (ZM, ZAM) or aluminium-zinc (AZ, galvalume).

33. A steel strip comprising, in addition to carbon, iron as a main constituent, an Mn content of 8.1 to 25.0 wt. % and optionally one or more of the alloy elements Al, Si, Cr, B, Ti, V, Nb and/or Mo with a metallic coat applied by means of hot-dipping, wherein, in a transition region between the metallic coat and a surface of the steel strip, a predominantly ferritic edge zone with more than 51 vol. % ferrite is formed, and wherein the predominantly ferritic edge zone has a thickness of between 0.25 to 1.3 μm and, as seen from the steel strip surface, consists of a pure iron layer with an average iron content of more than 96 wt. % and an oxygen-containing, iron-based layer containing more than 5 mass percent of oxygen thereon.

34. The steel strip as claimed in claim 33, wherein the predominantly ferritic edge zone has a thickness of between 0.3 and 1.0 μm

35. The steel strip as claimed in claim 33, comprising the following composition in wt. %:
C: 0.1% to 1.0%,
Mn: 8.1% to 25.0%,
Si: 0.01% to 3.0%,
Al: 1.0% to 8.0%,
optionally
Cr: 0.01% to 0.7%,
B: 0.001% to 0.08%,
Ti: 0.005% to 0.3%,
V: 0.005% to 0.3%,
Nb: 0.005% to 0.2%,
Mo: 0.005% to 0.7%,
P: ≤0.10%,
S: ≤0.010%,
with the remainder being iron and unavoidable impurities.

36. The steel strip as claimed in claim 33, wherein the metallic coat comprises of: aluminium-silicon (AS, AlSi), zinc (Z), zinc-aluminium (ZA), zinc-aluminium-iron (ZF/galvannealed), zinc-magnesium-aluminium (ZM, ZAM) or aluminium-zinc (AZ).

37. The steel strip as claimed in claim 36, wherein the metallic coat comprises zinc, and wherein the zinc coat contains 0.1 to 1 wt. % Al.

38. The steel strip as claimed in claim 36, wherein the metallic coat comprises zinc, and wherein the zinc coat contains 0.1 to 6 wt. % Al and 0.1 to 6 wt. % Mg.

39. The steel strip as claimed in claim 36, wherein the metallic coat comprises zinc, and wherein the zinc coat contains 5 to 15 wt. % Fe.

40. A steel strip for the production of parts for motor vehicles, said steel strip comprising, in addition to carbon, iron as a main constituent, an Mn content of 8.1 to 25.0 wt. % and optionally one or more of the alloy elements Al, Si, Cr, B, Ti, V, Nb and/or Mo with a metallic coat applied by means of hot-dipping, wherein, in a transition region between the metallic coat and a surface of the steel strip, a predominantly ferritic edge zone with more than 51 vol. % ferrite is formed, and wherein the predominantly ferritic edge zone has a thickness of between 0.25 to 1.3 μm and, as seen from the steel strip surface, consists of a pure iron layer with an average iron content of more than 96 wt. % and an oxygen-containing, iron-based layer containing more than 5 mass percent of oxygen thereon.
